(19) United States
(12) Patent Application Publication
(10) Pub. No.: US 2012/0261702 A1
(43) Pub. Date: Oct. 18, 2012

(54) LED, LED CHIP AND METHOD OF FORMING THE SAME

(76) Inventors: Xilin SU, Shenzhen (CN); Chunlin XIE, Shenzhen (CN); Hongpo HU, Shenzhen (CN); Wang ZHANG, Shenzhen (CN)

(21) Appl. No.: 13/457,955

(22) Filed: Apr. 27, 2012

Related U.S. Application Data
(63) Continuation of application No. PCT/CN2010/075760, filed on Aug. 6, 2010.

(30) Foreign Application Priority Data
Oct. 29, 2009 (CN) 200910109947.5

(51) Int. Cl. H01L 33/60

(52) U.S. Cl. 257/98; 438/29; 257/E33.06

(57) ABSTRACT

A method for manufacturing a light emitting diode chip is provided, comprising: providing a substrate, an upper surface of which comprising a plurality of micro-bulges formed thereon; forming a first type semiconductor layer, a light emitting layer and a second type semiconductor layer on the upper surface of the substrate successively; partially etching the second type semiconductor layer and the light emitting layer to form an electrode bonding area on the first type semiconductor layer; and forming a first electrode structure on the electrode bonding area and forming a second electrode structure on the second type semiconductor layer. A LED chip and a LED comprising the same are also provided.

### CROSS-REFERENCE TO RELATED APPLICATION

This application is a continuation of International Application No. PCT/CN2010/075760, filed Aug. 6, 2010, which claims priority to Chinese Application No. 200910109947.5, filed with the State Intellectual Property Office of People's Republic of China on Oct. 29, 2009, the entire contents of both of which are incorporated herein by reference.

### FIELD

The present disclosure relates to the semiconductor field, and more particularly to a light emitting diode (LED) chip, a method of forming the LED chip, and a LED using the same.

### BACKGROUND

A light emitting diode (LED) chip is an electroluminescent device, which illuminates by electron-hole recombination in the region near the P-N junction. A LED chip may be produced when an N-type layer, a light emitting layer, a P-type layer, an N-type electrode layer and a P-type electrode layer of the LED chip are formed successively on a substrate with a smooth plane by epitaxy or other processes. Because the lattice constant of the substrate material may not match that of the material for the epitaxial layer (the N-type layer, the light emitting layer and the P-type layer), when the above epitaxial layers are deposited on the substrate directly, the stress in the lattice cannot be released. This may result in high defects density in the epitaxial layers, which will increase the probability of non-radiative electron-hole recombination and decrease the luminous efficiency. In addition, the energy generated by the non-radiative recombination may be released as heat, which may increase the temperature of the LED and thus decrease the lifespan and stability thereof.

Moreover, according to the principle of light refraction, if light travels from a medium with a higher refractive index to a medium with a lower refractive index, it will be partially refracted at the boundary surface when crossing the boundary between the two media. However, if the incidence angle is equal to a critical angle, the light will be refracted such that it will travel along the boundary surface, in which case the refraction angle is 90°. If the incidence angle is greater than the critical angle, the light will stop crossing the boundary altogether and instead be totally reflected back internally, where the total internal reflection occurs. Because of the lack of package materials with a high refractive index, a resin is often used as the package material. The refractive index of resin is lower than that of the main material, GaN, of the LED chip. Thus, when both the total internal reflection and non-radiative electron-hole recombination occur in conventional LEDs, most of the light will be converted into heat, reducing the light extraction efficiency of the LED. It will also reduce the luminous efficiency of the LED, because the high temperature caused by heat may further lower the probability of the radiative electron-hole recombination. The high temperature may also affect the lifespan and stability of the LED. Therefore, conventional LEDs may have the defects of low light extraction efficiency and stability.

### SUMMARY

Provided herein are a light emitting diode (LED) chip with high light extraction efficiency, a method for forming the LED chip, and a LED comprising the LED chip.

According to an aspect of the present disclosure, a method for manufacturing a LED chip is provided, comprising:

providing a substrate, an upper surface of which comprising a plurality of micro-bulges formed thereon;

forming a first type semiconductor layer, a light emitting layer and a second type semiconductor layer on the upper surface of the substrate successively;

partially etching the second type semiconductor layer and the light emitting layer to form an electrode bonding area on the first type semiconductor layer; and

forming a first electrode structure on the electrode bonding area and forming a second electrode structure on the second type semiconductor layer.

In some embodiments, the method provided herein further comprises:

thinning a lower surface of the substrate;

providing a base plate comprising a third electrode structure corresponding to the first electrode structure and a fourth electrode structure corresponding to the second electrode structure; and

inverting the substrate, and coupling the third electrode structure to the first electrode structure and coupling the fourth electrode structure to the second electrode structure to form a LED flip chip.

According to another aspect of the present disclosure, a LED chip is provided, comprising:

a substrate with a plurality of micro-bulges on an upper surface thereof;

a first type semiconductor layer formed on the upper surface of the substrate;

an electrode bonding area formed on the first type semiconductor layer;

a light emitting layer formed on the first type semiconductor layer;

a second type semiconductor layer formed on the light emitting layer;

a first electrode structure formed on the electrode bonding area; and

a second electrode structure formed on the second type semiconductor layer.

In some embodiments, the LED chip provided herein further comprises a base plate, which comprises a third electrode structure corresponding to and connected with the first electrode structure, and a fourth electrode structure corresponding to and connected with the second electrode structure.

According to still another aspect of the present disclosure, a LED is provided, comprising:

a base;

a package body matched with the base;

a fifth electrode structure and a sixth electrode structure with an opposite polarity to the fifth electrode structure, disposed on the base; and

a LED chip mentioned above, disposed between the base and the package body,

which is energized by the third and fourth electrode structures.

In some embodiments of the present disclosure, the upper surface of the substrate is rough due to the plurality of micro-bulges formed thereon, which may reduce the probability of total internal reflection of the LED chip by changing the light transmission angle. It may also reduce the probability of non-radiative electron-hole recombination and improve the external quantum efficiency of the LED chip. Thus, the LED chip provided herein may have an increased light extraction efficiency. Moreover, because the probabilities of non-radiative electron-hole recombination and total internal reflection are reduced, the temperature of the LED chip may be decreased, thereby improving the lifespan and stability of the LED chip.

In some embodiments of the present disclosure, an epitaxial layer including the first type semiconductor layer, the light emitting layer and the second type semiconductor layer may be formed on the upper surface of the substrate by epitaxial lateral overgrowth (ELOG) or lateral epitaxial pattern substrate (LEPS) process, which may reduce the crystal structure defects in the epitaxial layer and thus increase the internal quantum efficiency of the LED chip.

In some embodiments of the present disclosure, the tops of the micro-bulges may be processed to be in a uniform crystal plane, which may reduce the probability of invalid electron-hole recombination in the epitaxial layer and improve the internal quantum efficiency of the LED chip.

Additional aspects and advantages of the embodiments of present invention will be given in part in the following descriptions, become apparent in part from the following descriptions, or be learned from the practice of the embodiments of the present invention.

### BRIEF DESCRIPTION OF THE DRAWINGS

The above and other features and advantages of the invention will be better understood from the following detailed descriptions taken in conjunction with the accompanying drawings, in which:

FIG. 1A is a process flow chart of manufacturing a LED chip according to a first embodiment of the present disclosure;

FIG. 1B is a diagram showing the meaning of roughness average Ra;

FIG. 1C is a diagram showing the meaning of peak spacing Rsm;

FIG. 2 is a process flow chart of manufacturing a LED chip according to a second embodiment of the present disclosure;

FIG. 3 is a cross-sectional view of a substrate of a LED chip according to a third embodiment of the present disclosure;

FIG. 4 is a cross-sectional view of a LED chip according to a third embodiment of the present disclosure;

FIG. 5 is a cross-sectional view of a LED chip according to a fourth embodiment of the present disclosure; and

FIG. 6 is a cross-sectional view of a light emitting diode according to a fifth embodiment of the present disclosure.

### DETAILED DESCRIPTION OF THE EMBODIMENTS

Reference will be made in detail to embodiments of the present disclosure. The embodiments described herein with reference to drawings are explanatory, illustrative, and used to generally understand the present disclosure. The embodiments shall not be construed to limit the present disclosure.

It should be understood that the following disclosure provides different embodiments, or examples, for implementing different features of the invention. Specific examples of components and arrangements are described below to simplify the present disclosure. These are, of course, merely illustrative and are not intended to limit the present disclosure. In addition, the present disclosure may repeatedly refer to numerals and/or letters in the various examples. This repetition is for the purpose of simplicity and clarity and does not in itself denote a relationship between the various embodiments and/or configurations under discussion. Moreover, the formation of a first feature over or on a second feature described below may include embodiments in which the first and second features are in direct contact, and may also include embodiments in which additional features may be formed interposing the first and second features, such that the first and second features may not be in direct contact.

In some embodiments, a method for manufacturing a LED chip may comprise:
a) providing a substrate, an upper surface of which comprising a plurality of micro-bulges formed thereon;
b) forming a first type semiconductor layer, a light emitting layer and a second type semiconductor layer on the upper surface of the substrate successively;
c) partially etching the second type semiconductor layer and the light emitting layer to form an electrode bonding area on the first type semiconductor layer; and
d) forming a first electrode structure on the electrode bonding area and forming a second electrode structure on the second type semiconductor layer.

In some embodiments of the present disclosure, the substrate may be chosen from, for example, a sapphire substrate, a silicon carbide substrate, a silicon substrate, a gallium arsenide substrate, an aluminum nitride substrate, and a gallium nitride substrate. In some embodiments, the upper surface of the substrate comprising a plurality of micro-bulges may be made rough and formed by grinding the upper surface of the substrate with, for example, an abrasive paper or other grinding machines. In some embodiments, the micro-bulge may have a pyramidal shape. The micro-bulges may change the light transmission angle, thereby reducing the probability of total internal reflection and improving the external quantum efficiency of the LED chip. Moreover, because the probabilities of non-radiative electron-hole recombination and total internal reflection may be reduced, the temperature of the LED chip may be decreased, thereby improving the lifespan and stability of the LED chip.

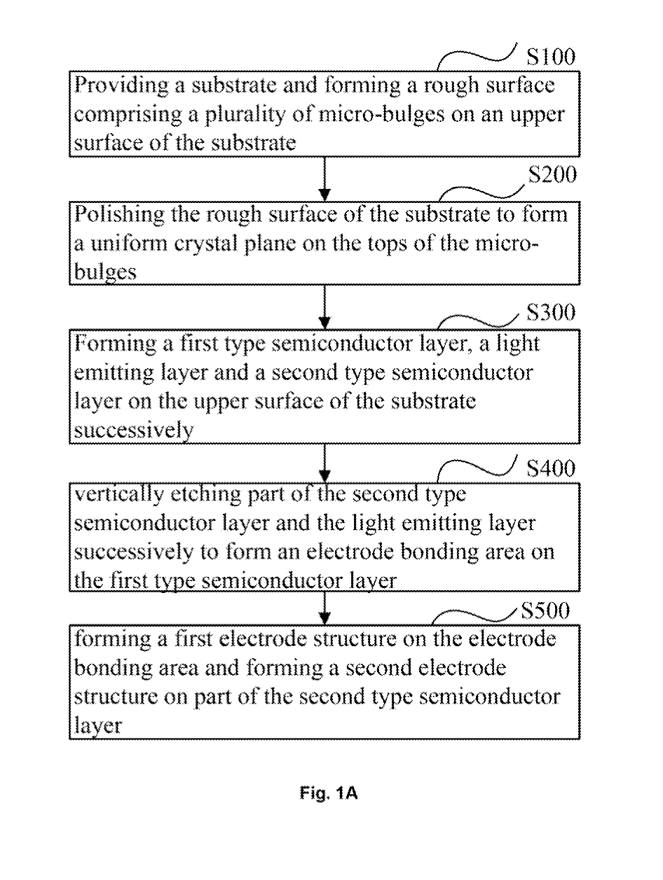

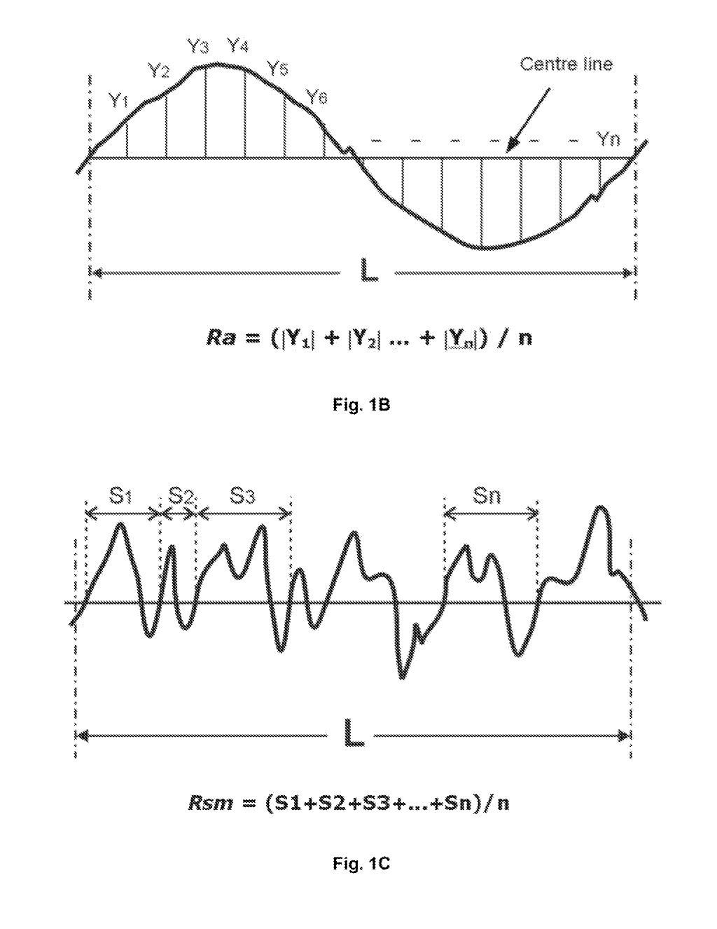

According to some embodiments of the present disclosure as shown in FIG. 1, the upper surface of the substrate may be polished to form a uniform crystal plane on the tops of the micro-bulges, that is to say, the tops of the micro-bulges may be in a uniform crystal plane after polishing. The uniform crystal plane means that the indices of the crystal planes are identical. In some embodiments, the micro-bulge may have a pyramidal frustum shape. In some embodiments, after polishing, the upper surface of the substrate may have a roughness average Ra ranging from about 0.05 μm to 5 μm and a peak spacing Rsm ranging from about 0.05 μm to 5 μm. As used herein and shown in FIGS. 1B and 1C, the term “roughness average” refers to the arithmetic average value of the departure of the profile from the centre line throughout the sampling length L, and the term “peak spacing” refers to the mean spacing between profile peaks at the centre line, measured within the sampling length L. Because the tops of the micro-bulges are in a uniform crystal plane, the crystal structure defects in the epitaxial layer may be decreased, thereby reducing the invalid electron-hole recombination in the epitaxial layer and improving the internal quantum efficiency of the LED chip. In addition, the temperature of the LED chip may be further decreased. As used herein, the term “epitaxial layer” includes the first type semiconductor layer, the light emitting layer and the second type semiconductor layer.

According to some embodiments of the present disclosure, the first type semiconductor layer, the light emitting layer and the second type semiconductor layer may be formed successively on the upper surface of the substrate. In some embodiments of the present disclosure, the first type semiconductor layer, the light emitting layer and the second type semiconductor layer may be formed successively on the upper surface of the substrate by epitaxial lateral overgrowth (ELOG) or lateral epitaxial pattern substrate (LEPS) process, which may reduce the threading dislocation defects. The amount of defects in an epitaxial layer grown on a uniform crystal plane may be reduced when compared with that in an epitaxial layer grown on different crystal planes. Thus, the method provided herein may decrease the probability of invalid electron-hole recombination, and further increase the internal quantum efficiency and luminous efficiency of the LED chip.

According to some embodiments of the present disclosure, the light emitting layer and the second type semiconductor layer maybe etched successively to form an electrode bonding area on the first type semiconductor layer.

According to some embodiments of the present disclosure, a first electrode structure may be formed on the electrode bonding area, and a second electrode structure may be formed on the second type semiconductor layer, by evaporation plating or magnetron sputtering. In some embodiments of the present disclosure, the first type semiconductor layer may be chosen from an N-type and P-type semiconductor layer, and the second type semiconductor may be the other. In some embodiments, the semiconductor material may comprise a Group III-V nitride material. In some embodiments, the Group III-V nitride material may be chosen from, for example, GaN, InGaN, AlGaN and AlGaInN. The material of the first electrode structure may be the same as or different from that of the second electrode structure. In some embodiments of the present disclosure, the materials of the first and second electrode structures may be chosen independently from, for example, Ti, Al, Pt, Cr and Au. In some embodiments, the materials of the first and second electrode structures may be Au. In some embodiments of the present disclosure, the first and second electrode structures may be formed independently by one metal layer or multiple metal layers.

In some embodiments of the present disclosure, after polishing the upper surface of the substrate, the method may further comprise corroding the substrate by using a corrosion solution at a temperature ranging from about 20° C. to 400° C. for about 5 minutes to 60 minutes. In some embodiments of the present disclosure, the corrosion solution may include 98% concentrated sulfuric acid (H₂SO₄) and 63% concentrated phosphoric acid (H₃PO₄) with a proportion ranging from about 1:1 to about 5:1. In some embodiments of the present disclosure, the method may further comprise, before step d), forming a current diffusing layer on the second type semiconductor layer. In some embodiments of the present disclosure, before the step of forming the current diffusing layer, the method may further comprise forming a two-dimensional electron gas diffusing layer on the second semiconductor layer. In some embodiments of the present disclosure, the method may further comprise processing the LED chip formed herein into a LED flip chip with the following steps:

thinning a lower surface of the substrate by mechanical grinding;

providing a base comprising a third electrode structure corresponding to the first electrode structure and a fourth electrode structure corresponding to the second electrode structure; and

inverting the substrate, coupling the third electrode structure to the first electrode structure and coupling the fourth electrode structure to the second electrode structure to form the LED flip chip.

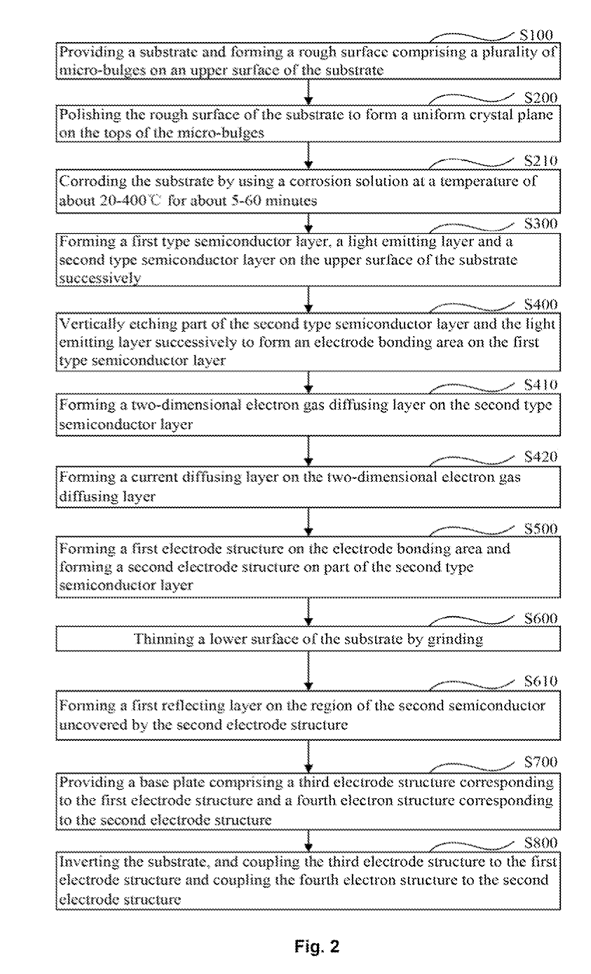

In some embodiments as shown in FIG. 2, the method for manufacturing a LED chip may comprise the following steps.

Step S100: A substrate, an upper surface of which comprising a plurality of micro-bulges formed thereon, may be provided. In some embodiments, the substrate may be a sapphire substrate. In some embodiments, the upper surface may be made rough and formed by mechanical grinding or etching. In some embodiments, the micro-bulge may be of a pyramidal shape.

Step S200: The upper surface of the substrate may be polished to form a uniform crystal plane on the tops of the micro-bulges. In some embodiments, this is performed by adjusting the rotation speed and the pressure of the polisher and thereby controlling the polishing speed and the accuracy according to different degrees of roughness of the upper surface of the substrate. In some embodiments, after polishing, the upper surface of the substrate may have a roughness average Ra ranging from about 0.05 μm to 5 μm and a peak spacing Rsm ranging from about 0.05 μm to 5 μm.

Step S210: The substrate may be corroded by using a corrosion solution including 98% concentrated sulfuric acid (H₂SO₄) and 63% concentrated phosphoric acid (H₃PO₄) with a proportion ranging from about 1:1 to about 5:1 at a temperature ranging from about 20° C. to 400° C. for about 5 minutes to 60 minutes. In some embodiment, the corrosion solution may include 98% concentrated sulfuric acid (H₂SO₄) and 63% concentrated phosphoric acid (H₃PO₄) with a proportion of about 3:1 at a temperature of about 50° C. for about 30 minutes. Thereby, the defect region including the inherent defect region of the substrate and the damaged layer introduced during mechanical grinding may be reduced by corroding, thus remarkably improving the crystal quality of the epitaxial layer, reducing the density of defects, and further improving the internal quantum efficiency of the LED chip. Furthermore, the reduction of the defect region may decrease the scattering loss of light on the boundary between the substrate and the epitaxial layer, thus further improving the external quantum efficiency of the LED chip.

Step S300: An N-type GaN layer as an example of a first type semiconductor layer, a light emitting layer, and a P-type GaN layer as an example of a second type semiconductor layer, may be formed successively on the upper surface of the substrate by LEPS. In some embodiments, the light emitting layer may be a multi-quantum well GaN layer.

Step S400: A part of the P-type GaN layer and a part of the light emitting layer may be vertically etched to form an electrode bonding area on the N-type GaN layer.

In some embodiments of the present disclosure, the method may further comprise Step S420 after Step S400, in which a current diffusing layer may be formed on the P-type GaN layer. In some embodiments, the current diffusing layer may be a transparent layer. In some embodiments, the current diffusing layer may be an indium tin oxide (ITO) layer. The introduction of the ITO layer may improve the uniform distribution of the current in the LED chip, increasing the circulation area of the current to improve the luminous efficiency of the LED chip.

In some embodiments of the present disclosure, the method may further comprise Step S410, wherein a two-dimensional electron gas diffusing layer may be formed between the P-type GaN layer and the current diffusing layer, improving the uniform distribution of the current in the LED chip and the utilization rate of the LED chip.

Step S500: A first electrode structure may be formed on the electrode bonding area and a second electrode structure may be formed on a first region of the P-type GaN layer. In some embodiments, the first and second electrode structures may be formed by evaporation plating or magnetron sputtering. In some embodiments, the first and second electrode structures may be independently a multi-layer metal film formed successively with a 5 nm Ti layer, a 200 nm Al layer, a 15 nm Ti layer and a 100 nm Au layer.

In some embodiments of the present disclosure, after Step S500, the following steps may be further performed to form a LED flip chip.

Step S600: A lower surface of the substrate may be thinned. In some embodiments, the thinning is performed by grinding. In some embodiments of the present disclosure, the thickness to be reduced may be determined by the thickness of the substrate, and the lower surface of the substrate may also become a rough surface after being grinded, which is beneficial to increase the light extraction efficiency.

In some embodiments of the present disclosure, the method described herein may further comprise the step S610, wherein a first reflecting layer may be formed on the region of the P-type GaN layer uncovered by the second electrode structure. In some embodiments, the first reflecting layer may include a metal layer. In some embodiments, the metal layer may be made of silver. In some embodiments, the first reflecting layer may have a high reflectivity and include a metal layer and a transparent dielectric layer with a low reflectivity.

Step S700: A base plate comprising a third electrode structure corresponding to the first electrode structure and a fourth electrode structure corresponding to the second electrode structure may be provided. In some embodiments, the base plate may include a rectangular silicon plate. In some embodiments, the base may further comprise a second reflecting layer, which may increase the light extraction efficiency of the LED chip.

Step S800: The substrate may be inverted, and the third electrode structure and the fourth electrode structure may be coupled to the first electrode structure and the second electrode structure, respectively, to form a LED flip chip. In some embodiments of the present disclosure, the third electrode structure and the fourth electrode structure may be coupled to the first electrode structure and the second electrode structure, respectively. In some embodiments, the coupling may be performed by using a conductive adhesive or bonding. The LED flip chip thus formed may have high light extraction efficiency and thermal conductivity, as well as improved lifespan and stability.

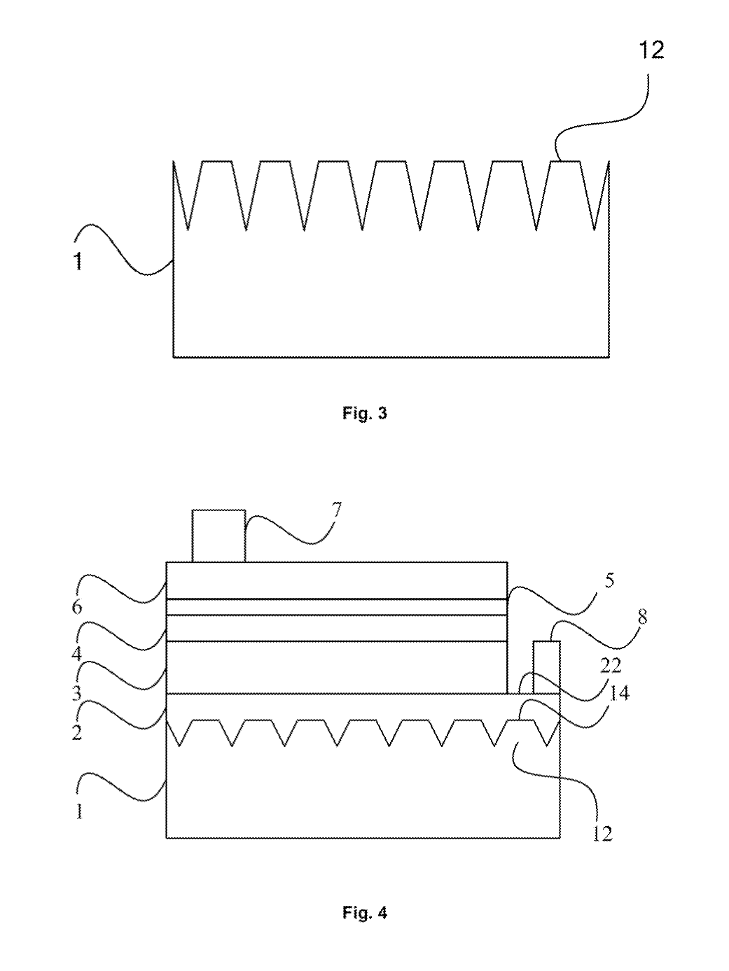

In some embodiments as shown in FIGS. 3 and 4, the LED chip described herein may comprise a substrate 1, a first type semiconductor layer 2, an electrode bonding area 22, a light emitting layer 3, a second type semiconductor layer 4, a first electrode structure 8, and a second electrode structure 7. The substrate 1 may comprise a plurality of micro-bulges 12 on an upper surface of the substrate 1. The first type semiconductor layer 2 may be formed on the upper surface of the substrate 1. The electrode bonding area 22 may be formed on a first region of the first type semiconductor layer 2. The light emitting layer 3 may be formed on a second region of the first type semiconductor layer 2. The second type semiconductor layer 4 may be formed on the light emitting layer 3. The first electrode structure 8 may be formed on the electrode bonding area 22. The second electrode structure 7 may be formed on a part of the second type semiconductor layer 4.

In some embodiments of the present disclosure, the tops of the micro-bulges 12 may be in a uniform crystal plane 14. The uniform crystal plane means that the indices of the crystal planes are identical. In some embodiments, the micro-bulge 12 may have a pyramidal frustum shape. In some embodiments, the upper surface of the substrate 1 may have a roughness average Ra ranging from about 0.05 μm to 5 μm and a peak spacing Rsm ranging from about 0.05 μm to 5 μm.

In some embodiments of the present disclosure, the substrate 1 may be chosen from, for example, a sapphire substrate, a silicon carbide substrate, a silicon substrate, a gallium arsenide substrate, an aluminum nitride substrate, and a gallium nitride substrate. In some embodiments, the substrate 1 may be a sapphire substrate.

In some embodiments of the present disclosure, the material of the first type semiconductor layer 2 may be one of a P-type semiconductor material and a N-type semiconductor material, and the material of the second semiconductor layer 4 may be the other. In some embodiments of the present disclosure, the P-type or N-type semiconductor materials may be chosen independently from Group III-V nitrides, including, but not limited to, gallium nitride (GaN), gallium indium nitride (InGaN), aluminum gallium nitride (AlGaN), and aluminum gallium indium nitride (AlGaInN). In some embodiments of the present disclosure, the material of the first type semiconductor layer 2 may be an N-type GaN material, and the material of the second type semiconductor layer 4 may be a P-type GaN material.

In some embodiments of the present disclosure, the first electrode structure 8 and the second electrode structure 7 may be identical or different, and may be independently a single-layer structure or a multi-layer structure. In some embodiments, the first electrode structure 8 and the second electrode structure 7 may be made of at least one metal chosen from, for example, gold, titanium, aluminum, platinum, and chrome. In some embodiments, the materials of the first electrode structure 8 and the second electrode structure 7 may be both gold. In some embodiments, the first electrode structure 8 and the second electrode structure 7 may independently have a thickness ranging from about 0.2 μm to 3 μm.

In some embodiments of the present disclosure, the LED chip described herein may further comprise a buffer layer formed between the substrate 1 and the N-type GaN layer 2. In some embodiments, the material of the buffer layer may be an intrinsic semiconductor. In some embodiments, the intrinsic semiconductor may be chosen from, for example, intrinsic gallium nitride (GaN) and aluminum gallium nitride (AlGaN). In some embodiments of the present disclosure, the N-type GaN layer 2, the light emitting layer 3 and the P-type GaN layer 4 are formed successively on the buffer layer to form an epitaxial layer. The epitaxial layer may be formed via lateral epitaxial overgrowth or lateral epitaxy using a Metal-Organic Chemical Vapor Deposition (MOCVD) device, which may effectively reduce the dislocation defects, thus reducing the lattice defects and further improving the internal quantum efficiency of the LED chip.

In some embodiments of the present disclosure, the LED chip may further comprise a current diffusing layer 6 formed between the P-type GaN layer 4 and the second electrode structure 7 and covering the P-type GaN layer 4. In some embodiments, the current diffusing layer 6 may include a transparent layer, such as an ITO layer.

In some embodiments of the present disclosure, the LED chip described herein may further comprise a two-dimensional electron gas diffusing layer 5 between the P-type GaN layer 4 and the current diffusing layer 6.

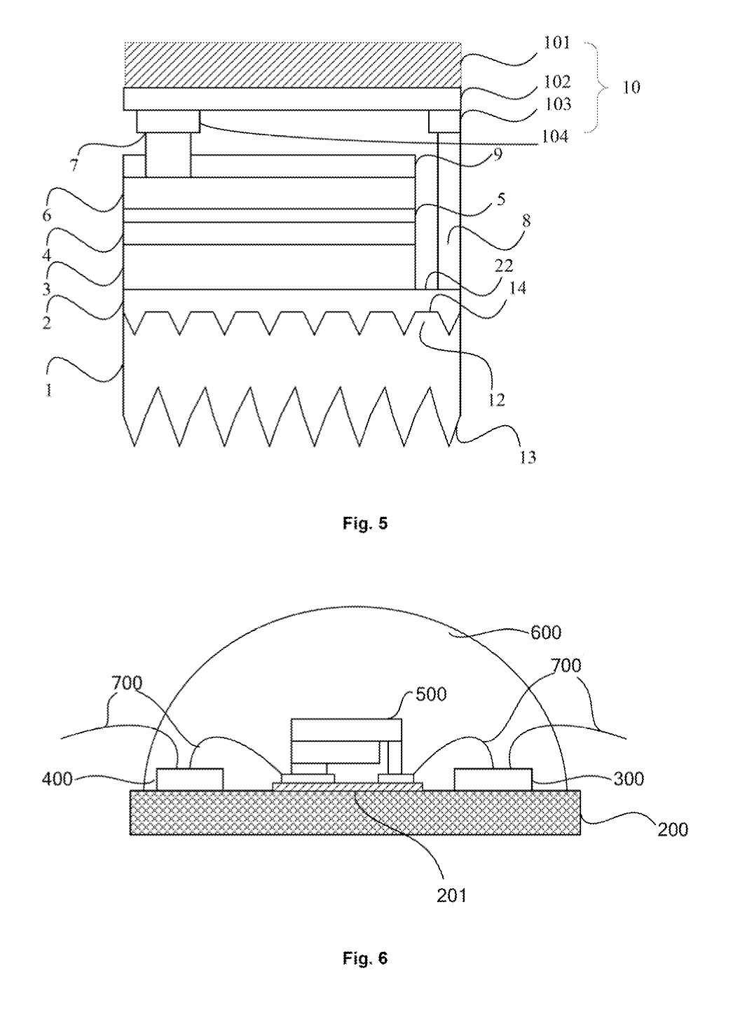

In some embodiments as shown in FIG. 5, a LED flip chip may be provided, which comprises a substrate 1, a first type semiconductor layer 2, an electrode bonding area, a light emitting layer 3, a second type semiconductor layer 4, a first electrode structure 8, a two-dimensional electron gas diffusing layer 5, a current diffusing layer 6, a second electrode structure 7, and a first reflecting layer 9. The substrate 1 may comprise a plurality of micro-bulges 12 with a uniform crystal plane 14 on an upper surface of the substrate 1. The first semiconductor layer 2 may be formed on the upper surface of the substrate 1. The electrode bonding area may be formed on a first region of the first type semiconductor layer 2. The light emitting layer 3 may be formed on a second region of the first type semiconductor layer 2. The second type semiconductor layer 4 may be formed on the light emitting layer 3. The first electrode structure 8 may be formed on the electrode bonding area. The two-dimensional electron gas diffusing layer 5 may be formed on the second type semiconductor layer 4. The current diffusing layer 6 may be formed on the two-dimensional electron gas diffusing layer 5. The second electrode structure 7 may be formed on a first region of the current diffusing layer 6. The first reflecting layer 9 may be disposed on a second region of the current diffusing layer 6 uncovered by the second electrode structure 7. The lower surface of the substrate 1 may be also a rough surface 13, to further improve the light extraction efficiency. The LED chip may further comprise a base plate 10. The base plate 10 may comprise a rectangular silicon plate 101, a third electrode structure 103 corresponding to the first electrode structure 8; and a fourth electrode structure 104 corresponding to the second electrode structure 7. In some embodiments of the present disclosure, a second reflecting layer 102 may be formed on the rectangular silicon plate 101 to improve the light extraction efficiency of the LED flip chip.

In some embodiments, the material of the substrate 1 may be sapphire. In some embodiments, the third electrode structure 103 and the fourth electrode structure 104 are coupled to the first electrode structure 8 and the second electrode structure 7, respectively, by using a conductive adhesive or bonding. In some embodiments, the first reflecting layer 9 may include a metal layer. In some embodiments, the metal layer is made of silver to improve the light extraction efficiency of the LED chip. In some embodiments, the reflecting layer 9 may have a high reflectivity and include a metal layer and a transparent dielectric layer with a low reflectivity. In some embodiments, the second reflecting layer 102 may increase not only the light extraction efficiency but also the thermal conductivity of the LED chip Because the heat generated by the LED chip may be dissipated rapidly to the base 10 via metal, the speed of thermal conductivity and thus the stability of the LED chip may be increased.

In some embodiments as shown in FIG. 6, a LED described herein may comprise a base 200, a package body 600 matched with the base 200, a fifth electrode structure 300, a sixth electrode structure 400 with an opposite polarity to the fifth electrode structure 300, and a LED chip 500. In some embodiments, the LED chip 500 may be the LED flip chip described herein, as shown in FIG. 6. The LED flip chip 500 may be disposed between the base 200 and the package body 600, and the fifth electrode structure 300 and the sixth electrode structure 400 are configured to connect the LED flip chip 500 with a power supply. In some embodiments of the present disclosure, the base 200 may comprise a fixing region 201, and the LED flip chip 500 may be disposed on the fixing region 201. In some embodiments, the fifth electrode structure 300 and the sixth electrode structure 400 are disposed on each side of the fixing region 201 respectively, and. In some embodiments of the present disclosure, the first electrode structure 8 or the third electrode structure 103 may be connected with the fifth electrode structure 300 via a connection wire 700, such as a gold wire, and the second electrode structure 7 or the fourth electrode structure 104 may be connected with the sixth electrode structure 400 via the connection wire 700. The connection wire 700 may also be configured to lead out the third electrode structure 103 and the fourth electrode structure 104 from the package body 600. In some embodiments of the present disclosure, the package body 600 may be made of a package resin with a phosphor.

When the LED described herein is energized by the fifth electrode structure 300 and the sixth electrode structure 400, the current passes through the light emitting layer 3 to make the light emitting layer 3 emit light, and then the light is emitted from the LED chip 500 by refraction. Because a plurality of micro-bulges are formed on the substrate 1 and the tops of the micro-bulges are in a uniform crystal plane, the internal and external quantum efficiencies of the LED chip may be improved simultaneously, thus increasing the luminance of the LED.

Although explanatory embodiments have been shown and described, it would be appreciated by those skilled in the art that changes, alternatives, and modifications can be made in the embodiments without departing from spirit and principles of the invention. Such changes, alternatives, and modifications all fall into the scope of the claims and their equivalents.

What is claimed is:

1. A method for manufacturing a light emitting diode (LED) chip, comprising:
a) providing a substrate, an upper surface of which comprising a plurality of micro-bulges formed thereon;
b) forming a first type semiconductor layer, a light emitting layer and a second type semiconductor layer on the upper surface of the substrate successively;
c) partially etching the second type semiconductor layer and the light emitting layer to form an electrode bonding area on the first type semiconductor layer; and
d) forming a first electrode structure on the electrode bonding area and forming a second electrode structure on the second type semiconductor layer.

2. The method according to claim 1, wherein step a) further comprises:
a1) polishing the upper surface of the substrate to form a uniform crystal plane on the tops of the plurality of micro-bulges.

3. The method according to claim 2, wherein the micro-bulge has a pyramidal frustum shape.

4. The method according to claim 1, wherein the first type semiconductor layer, the light emitting layer and the second type semiconductor layer are formed successively on the upper surface of the substrate via an epitaxial lateral overgrowth (ELOG) or lateral epitaxial pattern substrate (LEPS) process in step b).

5. The method according to claim 1, wherein the micro-bulge has a pyramidal shape.

6. The method according to claim 1, wherein the upper surface of the substrate has a roughness average (Ra) ranging from 0.05 μm to 5 μm.

7. The method according to claim 1, wherein the upper surface of the substrate has a peak spacing (Rsm) ranging from 0.05 μm to 5 μm.

8. The method according to claim 2, wherein step a) further comprises:
a2) corroding the substrate by using a corrosion solution at a temperature ranging from about 20° C. to 400° C. for about 5 minutes to 60 minutes after step a1.

9. The method according to claim 8, wherein the corrosion solution comprises 98% concentrated sulfuric acid (H₂SO₄) and 63% concentrated phosphoric acid (H₃PO₄) with a proportion ranging from about 1:1 to about 5:1.

10. The method according to claim 1, further comprising:
forming a current diffusing layer on the second type semiconductor layer before step d.

11. The method according to claim 10, before the step of forming the current diffusing layer, further comprising:
forming a two-dimensional electron gas diffusing layer on the second type semiconductor layer.

12. The method according to claim 1, after step d, further comprising:
thinning a lower surface of the substrate;
providing a base plate comprising a third electrode structure corresponding to the first electrode structure and a fourth electrode structure corresponding to the second electrode structure; and
inverting the substrate, and coupling the third electrode structure to the first electrode structure and coupling the fourth electrode structure to the second electrode structure to form a LED flip chip.

13. The method according to claim 12, before the step of thinning the lower surface of the substrate, further comprising:
forming a first reflecting layer on the region of the second semiconductor uncovered by the second electrode structure.

14. A light emitting diode (LED) chip, comprising:
a substrate, an upper surface of which comprising a plurality of micro-bulges formed thereon;
a first type semiconductor layer formed on the upper surface of the substrate;
an electrode bonding area formed on a first region of the first type semiconductor layer;
a light emitting layer formed on a second region of the first type semiconductor layer;
a second type semiconductor layer formed on the light emitting layer;
a first electrode structure formed on the electrode bonding area; and
a second electrode structure formed on the second type semiconductor layer.

15. The light emitting diode chip according to claim 14, wherein the tops of the plurality of micro-bulges are processed to be in a uniform crystal plane.

16. The light emitting diode chip according to claim 15, wherein the micro-bulge has a pyramidal frustum shape.

17. The light emitting diode chip according to claim 14, wherein the upper surface of the substrate has a roughness average (Ra) ranging from about 0.05 μm to 5 μm.

18. The light emitting diode chip according to claim 14, wherein the upper surface of the substrate has a peak spacing (Rsm) ranging from about 0.05 μm to 5 μm.

19. The light emitting diode chip according to claim 14, further comprising a current diffusing layer formed between the second type semiconductor layer and the second electrode structure.

20. The light emitting diode chip according to claim 19, further comprising a two-dimensional electron gas diffusing layer formed between the second type semiconductor layer and the current diffusing layer.

21. The light emitting diode chip according to claim 14, further comprising a base plate, which comprises a third electrode structure corresponding to and connected with the first electrode structure, and a fourth electrode structure corresponding to and connected with the second electrode structure.

22. The light emitting diode chip according to claim 21, wherein a first reflecting layer is formed on the region of the second type semiconductor uncovered by the second electrode structure.

23. A LED, comprising:
a base;
a package body matched with the base;
a fifth electrode structure and a sixth electrode structure with an opposite polarity to the fifth electrode structure; and
a LED chip according to claim 14.
